(19) United States
(12) Patent Application Publication
(10) Pub. No.: US 2022/0285655 A1
(43) Pub. Date: Sep. 8, 2022

(54) DISPLAY APPARATUS

(71) Applicant: SAMSUNG DISPLAY CO., LTD., Yongin-si (KR)

(72) Inventors: Hongyeon Lee, Yongin-si (KR); Seungyeon Jeong, Yongin-si (KR); Ohjeong Kwon, Yongin-si (KR); Hyeoji Kang, Yongin-si (KR); Sujeong Kim, Yongin-si (KR)

(21) Appl. No.: 17/477,764

(22) Filed: Sep. 17, 2021

(30) Foreign Application Priority Data
Mar. 5, 2021 (KR) 10-2021-0029659

(51) Int. Cl. H01L 51/52; H01L 27/32

(52) U.S. Cl. CPC H01L 51/5284; H01L 27/323; H01L 51/5237; H01L 51/5271

(57) ABSTRACT

A display apparatus includes a display element on a substrate, a low-reflection layer on the display element, a light blocking layer on the low-reflection layer, the light blocking layer defining an opening corresponding to an emission area of the display element, and the light blocking layer including a body part that absorbs visible light and a light absorbing agent that is disposed in the body part and absorbs light in a wavelength band of about 380 nanometers (nm) to about 500 nm, and a reflection adjustment layer filling the opening of the light blocking layer.

This application claims priority to Korean Patent Application No. 10-2021-0029659, filed on Mar. 5, 2021, and all the benefits accruing therefrom under 35 U.S.C. § 119, the content of which in its entirety is herein incorporated by reference.

### BACKGROUND

### 1. Field

Embodiments relate to a display apparatus, and more particularly, to a display apparatus in which visibility is improved.

### 2. Description of the Related Art

Display apparatuses are electronic apparatuses capable of providing information to users. Because such display apparatuses are thin and lightweight, user convenience may be improved.

### SUMMARY

However, in the existing display apparatuses, visibility is deteriorated due to reflection of external light.

Embodiments include a display apparatus in which a visibility is improved. However, this is merely an example, and the scope of the invention is not limited thereby.

Additional features will be set forth in part in the description which follows and, in part, will be apparent from the description, or may be learned by practice of the presented embodiments of the invention.

According to an embodiment of the invention, a display apparatus includes a display element on a substrate, a low-reflection layer on the display element, a light blocking layer on the low-reflection layer, the light blocking layer defining an opening corresponding to an emission area of the display element, and the light blocking layer including a body part that absorbs visible light and a light absorbing agent that is disposed in the body part and absorbs light in a wavelength band of about 380 nanometers (nm) to about 500 nm, and a reflection adjustment layer filling the opening of the light blocking layer.

In an embodiment, an amount of the light absorbing agent per unit volume in a first portion of the light blocking layer facing the substrate may be less than an amount of the light absorbing agent per unit volume in a second portion of the light blocking layer facing opposite to the substrate.

In an embodiment, surface energy of the light absorbing agent may be less than surface energy of a material included in the body part.

In an embodiment, the light absorbing agent may include at least one of a dye and a pigment.

In an embodiment, the light absorbing agent may include a yellowish material.

In an embodiment, the light absorbing agent may include a material having a fluorine-based substituent.

In an embodiment, the light absorbing agent may have a transmittance of about 0.5 percent (%) or less in a wavelength band of about 400 nm to about 490 nm.

In an embodiment, the display apparatus may further include a thin-film encapsulation layer on the low-reflection layer, and a touch sensor layer on the thin-film encapsulation layer, where the light blocking layer may be on the touch sensor layer.

In an embodiment, the light blocking layer may further include a protective agent having a surface energy less than a surface energy of the light absorbing agent.

In an embodiment, the light blocking layer may further include a first portion facing the substrate, a second portion facing opposite to the substrate, and a third portion between the first portion and the second portion, an amount of the light absorbing agent per unit volume in the third portion may be greater than an amount of the light absorbing agent per unit volume in the first portion or the second portion, and an amount of the protective agent per unit volume in the second portion may be greater than an amount of the protective agent per unit volume in the first portion or the third portion.

According to an embodiment of the invention, a display apparatus includes a first display element, a second display element, and a third display element on a substrate and emitting light of different colors from each other, a low-reflection layer integrally disposed on the first to third display elements, the low-reflection layer being unitary as a single body, a light blocking layer on the low-reflection layer, the light blocking layer defining openings corresponding to emission areas of the first to third display elements, and the light blocking layer including a body part that absorbs visible light and a light absorbing agent that is disposed in the body part and absorbs light in a wavelength band of about 380 nm to about 500 nm, and a reflection adjustment layer filling the openings of the light blocking layer and unitary as a single body to correspond to the first to third display elements.

In an embodiment, an amount of the light absorbing agent per unit volume in a first portion of the light blocking layer facing the substrate may be less than an amount of the light absorbing agent per unit volume in a second portion of the light blocking layer facing opposite to the substrate.

In an embodiment, surface energy of the light absorbing agent may be less than surface energy of a material included in the body part.

In an embodiment, the light absorbing agent may include at least one of a dye and a pigment.

In an embodiment, the light absorbing agent may include a yellowish material.

In an embodiment, the light absorbing agent may include a material having a fluorine-based substituent.

In an embodiment, the light absorbing agent may have a transmittance of about 0.5% or less in a wavelength band of about 400 nm to about 490 nm.

In an embodiment, the display apparatus may further include a thin-film encapsulation layer on the low-reflection layer, and a touch sensor layer on the thin-film encapsulation layer, where the light blocking layer may be on the touch sensor layer.

In an embodiment, the light blocking layer may further include a protective agent having a surface energy less than a surface energy of the light absorbing agent.

In an embodiment, the light blocking layer may further include a first portion facing the substrate, a second portion facing opposite to the substrate, and a third portion between the first portion and the second portion, an amount of the light absorbing agent per unit volume in the third portion may be greater than an amount of the light absorbing agent per unit volume in the first portion or the second portion, and an amount of the protective agent per unit volume in the second portion may be greater than an amount of the protective agent per unit volume in the first portion or the third portion.

Other embodiments, features, and advantages of the invention will become better understood through the accompanying drawings, the claims and the detailed description.

### BRIEF DESCRIPTION OF THE DRAWINGS

The above and other embodiments, features, and advantages of the invention will be more apparent from the following description taken in conjunction with the accompanying drawings, in which:

FIG. 1 is a schematic plan view of an embodiment of a display apparatus;

FIG. 2 is an equivalent circuit diagram of an embodiment of a pixel circuit that drives an organic light-emitting diode;

FIG. 3A is an enlarged plan view of a portion of an embodiment of a display apparatus;

FIG. 3B is an enlarged plan view of a portion an embodiment of a display apparatus;

FIG. 4A is a schematic cross-sectional view of an embodiment of a display apparatus;

FIG. 4B is a schematic cross-sectional view of another embodiment of a display apparatus;

FIG. 5 is a graph showing light transmittance of an embodiment of a reflection adjustment layer;

FIGS. 6A and 6B are cross-sectional views of an embodiment of a display apparatus;

FIGS. 7A and 7B are cross-sectional views of an embodiment of a display apparatus;

FIG. 8 is a graph showing reflectance of a light blocking layer itself; and

FIGS. 9 and 10 are graphs showing reflectance of a display panel.

### DETAILED DESCRIPTION

Reference will now be made in detail to embodiments, examples of which are illustrated in the accompanying drawings, where like reference numerals refer to like elements throughout. In this regard, the embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the description allows for various changes and numerous embodiments, certain embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

The embodiments of the disclosure will be described below in more detail with reference to the accompanying drawings. Those elements that are the same or are in correspondence with each other are rendered the same reference numeral regardless of the figure number, and redundant explanations are omitted.

It will be understood that although the terms “first,” “second,” etc. may be used herein to describe various elements, these elements should not be limited by these terms. These terms are only used to distinguish one element from another.

The singular forms “a,” “an,” and “the” as used herein are intended to include the plural forms as well unless the context clearly indicates otherwise.

It will be further understood that the terms “comprises” and/or “comprising” used herein specify the presence of stated features or elements, but do not preclude the presence or addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Also, sizes of elements in the drawings may be exaggerated or reduced for convenience of explanation. For example, because sizes and thicknesses of elements in the drawings are arbitrarily illustrated for convenience of explanation, the disclosure is not limited thereto.

When a certain embodiment may be implemented differently, a specific process order may be performed differently from the described order. For example, two consecutively described processes may be performed substantially at the same time or performed in an order opposite to the described order.

In this specification, the expression “A and/or B” indicates only A, only B, or both A and B. The expression “at least one of A and B” indicates only A, only B, or both A and B.

It will be further understood that, when layers, regions, or components are also referred to as being connected to each other, they may be directly connected to each other or indirectly connected to each other with intervening layers, regions, or components therebetween. For example, when layers, regions, or components are referred to as being electrically connected to each other, they may be directly electrically connected to each other or indirectly electrically connected to each other with intervening layers, regions, or components therebetween.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

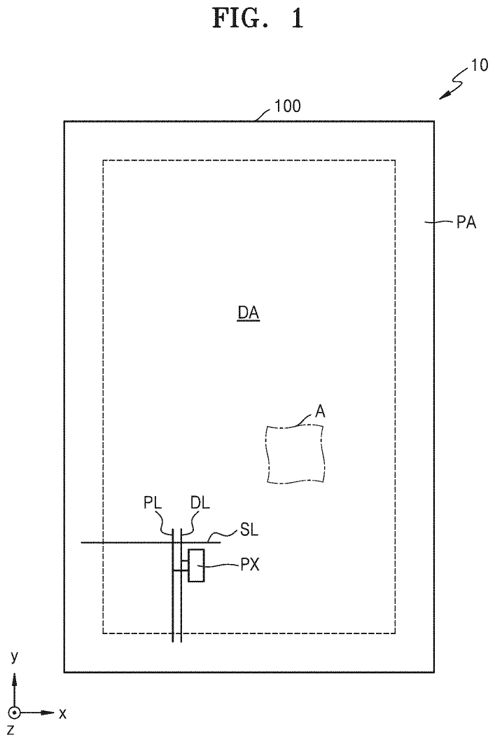

FIG. 1 is a schematic plan view of an embodiment of a display apparatus. As illustrated in FIG. 1, the display apparatus in the illustrated embodiment includes a display panel 10. Any display apparatus may be used as long as the display apparatus includes the display panel 10. In an embodiment, the display apparatus may be various apparatuses such as a smartphone, a tablet personal computer, a laptop, a television, or a billboard.

The display panel 10 may include a display area DA and a peripheral area PA outside the display area DA. The display area DA having a quadrangular (e.g., rectangular) shape is illustrated in FIG. 1. However, the invention is not limited thereto. The display area DA may have various shapes, for example, a circular shape, an elliptical shape, a polygonal shape, and a specific figure.

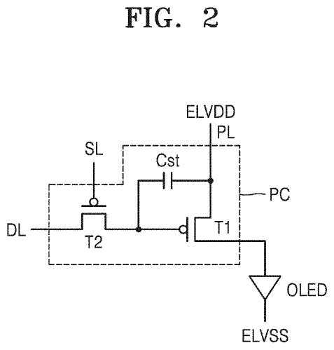

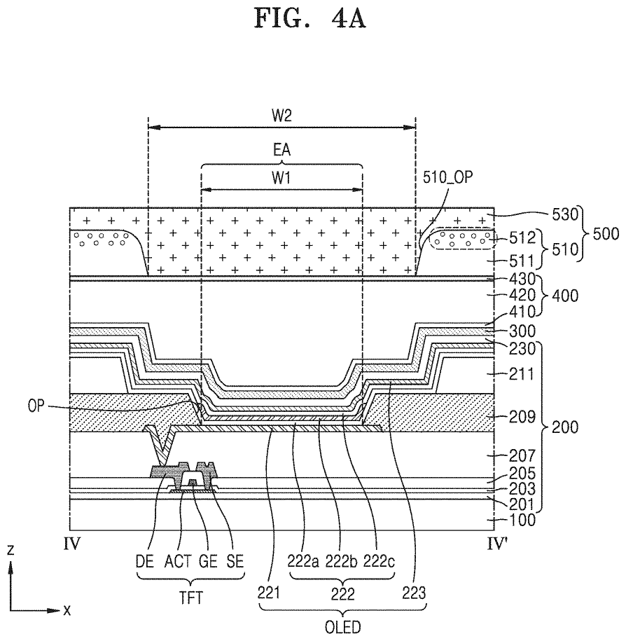

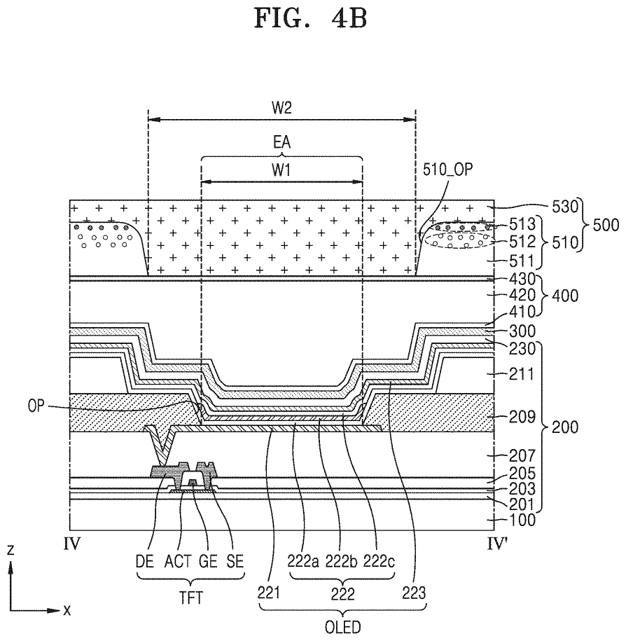

The display area DA is a part that displays an image, and a plurality of sub-pixels PX may be arranged in the display area DA. Each of the sub-pixels PX may include a display element such as an organic light-emitting diode OLED (refer to FIG. 2). Each of the sub-pixels Pa may emit, for example, red light, green light, blue light, or white light. Each of the sub-pixels PX may be connected to a pixel circuit including a thin-film transistor TFT (refer to FIG. 4A), a storage capacitor, or the like. The pixel circuit may be connected to scan lines SL which transmit a scan signal, data lines DL which crosses the scan lines SL and transmit a data signal, and driving voltage lines PL which apply a driving voltage. The scan lines SL may extend in the x direction, and the data lines DL and the driving voltage lines PL may extend in the y direction.

The sub-pixels PX may emit light when the pixel circuit is driven. The display area DA may provide a predetermined image through light emitted from the sub-pixels PX. In the specification, the sub-pixel PX may be defined as an emission area that emits light of any one of red, green, blue, and white colors, as described above.

The peripheral area PA is an area in which the sub-pixels PX are not arranged and may be an area that does not provide an image. A terminal part, to which a printed circuit board or a driver integrated circuit (“IC”) including a power supply line and a driving circuit which drive the sub-pixels PX is connected, may be arranged in the peripheral area PA.

Because the display panel 10 includes a substrate 100, the substrate 100 may have the display area DA and the peripheral area PA. Hereinafter, for convenience, the substrate 100 will be described as having the display area DA and the peripheral area PA.

Hereinafter, an organic light-emitting display apparatus will be described as an embodiment of the display apparatus. However, the display apparatus according to the invention is not limited thereto. In an embodiment, the display apparatus may include an inorganic light-emitting display (or an inorganic electroluminescence (“EL”) display) or a quantum dot light-emitting display, for example. In an embodiment, an emission layer of a display element in the display apparatus may include an organic material or an inorganic material, for example. Quantum dots may be disposed on the path of light emitted from the emission layer.

FIG. 2 is an equivalent circuit diagram of an embodiment of a pixel circuit that drives an organic light-emitting diode OLED. As illustrated in FIG. 2, the organic light-emitting diode OLED may be connected to a pixel circuit PC. The organic light-emitting diode OLED may emit, for example, red light, green light, blue light, or white light. The pixel circuit PC may include a first thin-film transistor T1, a second thin-film transistor T2, and a storage capacitor Cst. Each of the first thin-film transistor T1 and the second thin-film transistor T2 may include an oxide semiconductor thin-film transistor with a semiconductor layer including an oxide semiconductor, or a silicon semiconductor thin-film transistor with a semiconductor layer including polysilicon.

The first thin-film transistor T1 may include a driving thin-film transistor. The first thin-film transistor T1 may be connected to a driving voltage line PL and the storage capacitor Cst and may control a driving current flowing from the driving voltage line PL to the organic light-emitting diode OLED in response to a voltage value stored in the storage capacitor Cst. The organic light-emitting diode OLED may emit light having a predetermined luminance according to the driving current.

The second thin-film transistor T2 may include a switching thin-film transistor. The second thin-film transistor T2 may be connected to a data line DL. The second thin-film transistor T2 may transmit data input from the data line DL to the first thin-film transistor T1 in response to a switching voltage input from the scan line SL.

The storage capacitor Cst may be connected to the second thin-film transistor T2 and the driving voltage line PL. The storage capacitor Cst may store a voltage corresponding to a difference between a voltage received from the second thin-film transistor T2 and a first driving voltage ELVDD supplied to the driving voltage line PL.

The organic light-emitting diode OLED may include a first electrode connected to the first thin-film transistor T1 and a second electrode which receives a second driving voltage ELVSS. In an embodiment, a voltage level of the second driving voltage ELVSS may be less than that of the first driving voltage ELVDD. In an alternative embodiment, the second electrode of the organic light-emitting diode OLED may be connected to ground to receive a voltage of a 0 volt (V).

Although FIG. 2 illustrates that the pixel circuit PC includes two thin-film transistors T1 and T2 and one storage capacitor Cst, the invention is not limited thereto. In another embodiment, the number of thin-film transistors or the number of storage capacitors may be variously changed according to the design of the pixel circuit PC.

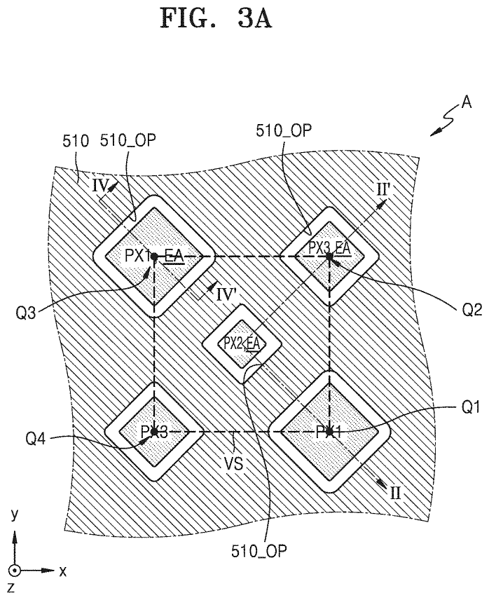

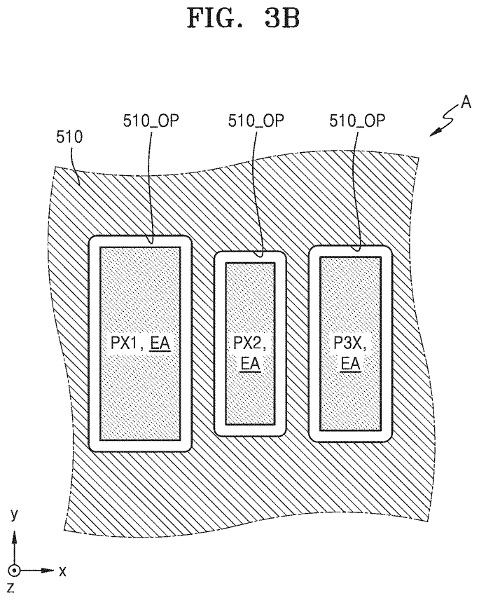

FIG. 3A is an enlarged plan view of an embodiment of a portion of a display apparatus. FIG. 3A is an enlarged plan view of a configuration of an embodiment that may be included in region A of FIG. 1. FIG. 3B is an enlarged plan view of another embodiment of a portion of a display apparatus. FIG. 3B is an enlarged plan view of a configuration of another embodiment that may be included in region A of FIG. 1.

As illustrated in FIG. 3A, the display apparatus may include a plurality of sub-pixels PX. Each of the sub-pixels PX may be any one of a first sub-pixel PX1, a second sub-pixel PX2, and a third sub-pixel PX3, which emit light of different colors from each other. The first sub-pixel PX1 may emit blue light, the second sub-pixel PX2 may emit green light, and the third sub-pixel PX3 may emit red light. However, the invention is not limited thereto. In an embodiment, the first sub-pixel PX1 may emit green light, the second sub-pixel PX2 may emit red light, and the third sub-pixel PX3 may emit blue light, for example.

In a plan view, the first sub-pixel PX1, the second sub-pixel PX2, and the third sub-pixel PX3 may have a quadrangular shape among polygonal shapes. In this case, the polygonal or quadrangular shape includes a shape with rounded vertices. That is, the first sub-pixel PX1, the second sub-pixel PX2, and the third sub-pixel PX3 may have a quadrangular shape with rounded vertices. However, the invention is not limited thereto. In an embodiment, the first sub-pixel PX1, the second sub-pixel PX2, and the third sub-pixel PX3 may have a circular shape or an elliptical shape.

The first sub-pixel PX1, the second sub-pixel PX2, and the third sub-pixel PX3 may have different sizes from each other. In an embodiment, the area of the second sub-pixel PX2 may be less than the areas of the first sub-pixel PX1 and the third sub-pixel PX3, for example. However, the invention is not limited thereto. In an embodiment, the first sub-pixel PX1, the second sub-pixel PX2, and the third sub-pixel PX3 may have substantially the same size, for example.

In the specification, the sizes of the first sub-pixel PX1, the second sub-pixel PX2, and the third sub-pixel PX3 may mean the size of an emission area EA of a display element implementing each sub-pixel PX. The emission area EA may be defined by an opening (refer to OP of FIG. 4A) of a pixel defining layer (refer to 209 of FIG. 4A).

Openings 510_OP corresponding to the sub-pixels PX may be defined in A light blocking layer 510 that absorbs external light. The opening 510_OP may be an area provided by removing a portion of the light blocking layer 510. Light from the display element may be emitted to the outside through the openings 510_OP. The light blocking layer 510 may include a material that absorbs external light, and thus, visibility of the display apparatus may be improved.

In a plan view, the openings 510_OP of the light blocking layer 510 may be arranged to surround the sub-pixels PX1, PX2, and PX3. In an embodiment, the opening 510_OP of the light blocking layer 510 may have a quadrangular (e.g., rectangular) shape with rounded corners. The areas of the openings 510_OP may be greater than the areas of the corresponding sub-pixels PX1, PX2, and PX3. However, the invention is not limited thereto. The areas of the openings 510_OP may be substantially the same as the areas of the corresponding sub-pixels PX1, PX2, and PX3.

The first sub-pixel PX1, the second sub-pixel PX2, and the third sub-pixel PX3 may be arranged in a pentile form. That is, assuming a virtual quadrangle VS in which the center point of the second sub-pixel PX2 is the center point of the quadrangle, the first sub-pixel PX1 may be arranged at a first vertex Q1, and the third sub-pixel PX3 may be arranged at a second vertex Q2 adjacent to the first vertex Q1. Also, the first sub-pixel PX1 may be arranged at a third vertex Q3 disposed at a position symmetrical to the first vertex Q1 based on the center point of the virtual quadrangle VS, and the third sub-pixel PX3 may be arranged at a fourth vertex Q4 disposed at a position symmetrical to the second vertex Q2 based on the center point of the virtual quadrangle VS. The virtual quadrangle VS may be a square. The first sub-pixels PX1 and the third sub-pixels PX3 may be alternately arranged in the x-axis direction and the y-axis direction crossing the x-axis direction. The second sub-pixel PX2 may be surrounded by the first sub-pixels PX1 and the third sub-pixels PX3.

FIG. 3A illustrates that the first sub-pixel PX1, the second sub-pixel PX2, and the third sub-pixel PX3 are arranged in a pentile form. However, the invention is not limited thereto. In an embodiment, as illustrated in FIG. 3B, the first sub-pixel PX1, the second sub-pixel PX2, and the third sub-pixel PX3 may be arranged in a stripe form. That is, the first sub-pixel PX1, the second sub-pixel PX2, and the third sub-pixel PX3 may be sequentially arranged in the x-axis direction, for example. The sub-pixels PX in another embodiment may also be arranged in a mosaic form.

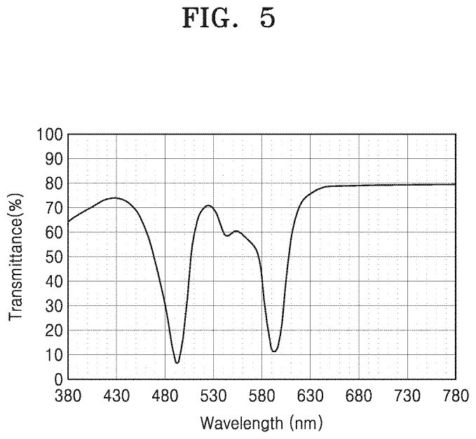

FIG. 4A is a schematic cross-sectional view of an embodiment of a display apparatus. FIG. 4B is a schematic cross-sectional view of a display apparatus. FIGS. 4A and 4B are cross-sectional views of the display apparatus taken along line IV-IV′ of FIG. 3A. FIG. 5 is a graph showing an embodiment of light transmittance of a reflection adjustment layer 530.

As illustrated in FIG. 4A, the display apparatus in the embodiment may include an organic light-emitting diode OLED on a substrate 100, and may have a structure in which a display layer 200, a low-reflection layer 300, a thin-film encapsulation layer 400, and an anti-reflective layer 500 are stacked on the substrate 100.

The substrate 100 may include glass, metal, or a polymer resin. When at least a portion of the display apparatus is flexible or bendable, the substrate 100 needs to be flexible or bendable. In this case, the substrate 100 may include, for example, a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. In other embodiments, the substrate 100 may be variously modified. In an embodiment, the substrate 100 may have a multilayer structure that includes two layers including the above-described polymer resin and a barrier layer between the two layers and including an inorganic material (e.g., silicon oxide, silicon nitride, silicon oxynitride, etc.), for example. Furthermore, when the substrate 100 is not bendable, the substrate 100 may include glass or the like.

The display layer 200 may include a buffer layer 201, a gate insulating layer 203, an inter-insulating layer 205, a planarization layer 207, a pixel defining layer 209, a spacer 211, an organic light-emitting diode OLED, and a thin-film transistor TFT. In an embodiment, the display layer 200 may further include a capping layer 230 on the organic light-emitting diode OLED.

The buffer layer 201 may be on the substrate 100, may reduce or prevent infiltration of foreign material, moisture, or ambient air from below the substrate 100, and may provide a flat surface on the substrate 100. The buffer layer 201 may include an inorganic material such as an oxide or a nitride, an organic material, or an organic/inorganic composite material, and may have a single-layer or multilayer structure including an inorganic material and an organic material. A barrier layer (not illustrated) that blocks infiltration of ambient air may be further included between the substrate 100 and the buffer layer 201. The buffer layer 201 may include silicon oxide (SiO₂) or silicon nitride (SiNₓ).

A thin-film transistor TFT may be on the buffer layer 201. The thin-film transistor TFT may include a semiconductor layer ACT, a gate electrode GE, a source electrode SE, and a drain electrode DE. The thin-film transistor TFT may be connected to the organic light-emitting diode OLED and drive the organic light-emitting diode OLED.

The semiconductor layer ACT may be on the buffer layer 201 and may include polysilicon. In another embodiment, the semiconductor layer ACT may include amorphous silicon. In another embodiment, the semiconductor layer ACT may include an oxide including at least one of indium (In), gallium (Ga), tin (Sn), zirconium (Zr), vanadium (V), hafnium (Hf), cadmium (Cd), germanium (Ge), chromium (Cr), titanium (Ti), and zinc (Zn), for example. The semiconductor layer ACT may include a channel region, and a drain region and a source region doped with impurities.

The gate electrode GE, the source electrode SE, and the drain electrode DE may include various conductive materials. The gate electrode GE may include at least one of molybdenum, aluminum, copper, and titanium. In an embodiment, the gate electrode GE may have a single molybdenum layer or a three-layer structure including a molybdenum layer, an aluminum layer, and a molybdenum layer, for example. The source electrode SE and the drain electrode DE may include at least one of copper, titanium, and aluminum. In an embodiment, the source electrode SE and the drain electrode DE may have a three-layer structure including a titanium layer, an aluminum layer, and a titanium layer, for example.

In order to ensure insulation between the semiconductor layer ACT and the gate electrode GE, the gate insulating layer 203 including an inorganic material such as silicon oxide, silicon nitride, and/or silicon oxynitride may be between the semiconductor layer ACT and the gate electrode GE. Also, the inter-insulating layer 205 including an inorganic material such as silicon oxide, silicon nitride, and/or silicon oxynitride may be on the first gate electrode GE, and the source electrode SE and the drain electrode DE may be on the inter-insulating layer 205. The insulating layer including the inorganic material may be formed or provided through chemical vapor deposition (“CVD”) or atomic layer deposition (“ALD”). The same may apply to the following embodiments and modifications thereof.

The planarization layer 207 may be on the thin-film transistor TFT. In order to provide a flat upper surface, after the planarization layer 207 is formed or provided, chemical and mechanical polishing may be performed on the upper surface of the planarization layer 207. The planarization layer 207 may include, for example, an organic material such as acryl, benzocyclobutene (“BCB”), or hexamethyldisiloxane (“HMDSO”). Although FIG. 4A illustrates that the planarization layer 207 is a single layer, the planarization layer 207 may be multiple layers in another embodiment.

A pixel electrode 221 may be on the planarization layer 207. The pixel electrode 221 may be arranged for each sub-pixel PX. The pixel electrodes 221 corresponding to the neighboring sub-pixels PX may be spaced apart from each other.

The pixel electrode 221 may include a reflective electrode. In this case, the pixel electrode 221 may include a reflective layer including silver (Ag), magnesium (Mg), aluminum (Al), platinum (Pt), palladium (Pd), gold (Au), nickel (Ni), neodymium (Nd), Iridium (Ir), chromium (Cr), or any combinations thereof, and a transparent or semitransparent electrode layer on the reflective layer. The transparent or semitransparent electrode layer may include at least one of indium tin oxide (“ITO”), indium zinc oxide (“IZO”), zinc oxide (ZnO), indium oxide (In₂O₃), indium gallium oxide (“IGO”), and aluminum zinc oxide (“AZO”). In an embodiment, the pixel electrode 221 may have a stack structure of ITO/Ag/ITO, for example.

The pixel defining layer 209 may be on the pixel electrode 221. Openings OP exposing the central portions of the pixel electrodes 221 may be defined in the pixel defining layer 209. The pixel defining layer 209 may cover an edge of the pixel electrode 221 and prevent an electric arc or the like from occurring on the edge of the pixel electrode 221 by increasing the distance between the edge of the pixel electrode 221 and an opposite electrode 223. The pixel defining layer 209 may include, for example, an organic material such as polyimide or HMDSO.

In some embodiments, the pixel defining layer 209 may include a light blocking material. The light blocking material may include carbon black, carbon nanotubes, a resin or paste including black dye, metal particles (e.g., nickel, aluminum, molybdenum, and alloys thereof), metal oxide particles (e.g., chromium oxide), or metal nitride particles (e.g., chromium nitride). The arrangement of the pixel defining layer 209 including the light blocking material may reduce the reflection of external light caused by metal structures below the pixel defining layer 209.

An intermediate layer 222 may be on the pixel electrode 221 and the pixel defining layer 209. The intermediate layer 222 may include a first common layer 222a, an emission layer 222b, and a second common layer 222c.

The emission layer 222b may be arranged inside the opening OP of the pixel defining layer 209. The emission layer 222b may include an organic material including a fluorescent or phosphorescent material capable of emitting blue light, green light, or red light. The above-described organic material may include a low molecular weight organic material or a high molecular weight organic material.

The first common layer 222a and the second common layer 222c may be below and above the emission layer 222b, respectively. The first common layer 222a may include, for example, a hole transport layer (“HTL”), or may include an HTL and a hole injection layer (“HIL”). The second common layer 222c may include, for example, an electron transport layer (“ETL”), or may include an ETL and an electron injection layer (“EIL”). In some embodiments, the second common layer 222c may not be provided.

While the emission layer 222b is arranged for each pixel so as to correspond to the opening OP of the pixel defining layer 209, the first common layer 222a and the second common layer 222c may be unitary as a single body to completely cover the substrate 100. In other words, the first common layer 222a and the second common layer 222c may be unitary as a single body to completely cover the display area DA of the substrate 100.

The opposite electrode 223 may be a cathode that is an electron injection electrode. The opposite electrode 223 may include a conductive material having a low work function. In an embodiment, the opposite electrode 223 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof, for example. In an alternative embodiment, the opposite electrode 223 may further include a layer such as ITO, IZO, ZnO, or In₂O₃ on the (semi)transparent layer including the above-described material. Layers from the pixel electrode 221 to the opposite electrode 223 may constitute the organic light-emitting diode OLED.

A spacer 211 may be on the pixel defining layer 209. The spacer 211 may prevent the layers between the substrate 100 and the spacer 211 from being damaged by a mask used in the process of forming the emission layer 222b. The spacer 211 may include the same material as that of the pixel defining layer 209. In some embodiments, the spacer 211 may include a light blocking material.

In an embodiment, the display apparatus may further include a capping layer 230 on the organic light-emitting diode OLED. The capping layer 230 may improve the luminescence efficiency of the organic light-emitting diode OLED based on the principle of constructive interference. The capping layer 230 may include, for example, a material exhibiting a refractive index of 1.6 or more for light having a wavelength of 589 nanometers (nm). The capping layer 230 may have a thickness of about 1 nm to about 200 nm along the z direction. In an embodiment, the capping layer 230 may have a thickness of about 5 nm to about 150 nm, or about 10 nm to about 100 nm, for example.

The capping layer 230 may include an organic capping layer including an organic material, an inorganic capping layer including an inorganic material, or a composite capping layer including an organic material and an inorganic material. In an embodiment, the capping layer 230 may include carbocyclic compounds, heterocyclic compounds, amine group-containing compounds, porphine derivatives, phthalocyanine derivatives, naphthalocyanine derivatives, alkali metal complexes, alkaline earth metal complexes, or any combinations thereof, for example. The carbocyclic compounds, the heterocyclic compounds, and the amine group-containing compounds may be optionally substituted with a substituent including O, N, S, Se, Si, F, Cl, Br, I, or any combinations thereof.

The low-reflection layer 300 may be on the capping layer 230. Because the capping layer 230 may be on the display element, the low-reflection layer 300 may be on the display element. The low-reflection layer 300 may include an inorganic material having a low reflectance. The low-reflection layer 300 may include ytterbium (Yb), bismuth (Bi), cobalt (Co), molybdenum (Mo), titanium (Ti), zirconium (Zr), aluminum (Al), chromium (Cr), niobium (Nb), platinum (Pt), tungsten (W), indium (In), tin (Sn), iron (Fe), nickel (Ni), tantalum (Ta), manganese (Mn), zinc (Zn), germanium (Ge), or any combinations thereof. The inorganic material included in the low-reflection layer 300 may have an absorption coefficient of about 0.5 or more. In an embodiment, the inorganic material included in the low-reflection layer 300 may have a refractive index of about 1 or more. In an embodiment, the low-reflection layer 300 may have a thickness of about 0.1 nm to about 50 nm.

The low-reflection layer 300 may reduce the reflectance of external light by inducing destructive interference between light incident into the interior of the display apparatus and light reflected from a metal below the opening. The low-reflection layer 300 may improve display quality and visibility of the display apparatus by reducing the reflectance of external light.

The thin-film encapsulation layer 400 may be on the low-reflection layer 300. The thin-film encapsulation layer 400 may include at least one inorganic encapsulation layer and at least one organic encapsulation layer. In an embodiment, as illustrated in FIG. 4A, the thin-film encapsulation layer 400 may include a first inorganic encapsulation layer 410, an organic encapsulation layer 420, and a second inorganic encapsulation layer 430, for example.

The first inorganic encapsulation layer 410 and the second inorganic encapsulation layer 430 may include an inorganic insulating material such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO). The first inorganic encapsulation layer 410 and the second inorganic encapsulation layer 430 may have a single layer structure or a multiple layer structure including the above-described inorganic insulating material.

The organic encapsulation layer 420 may alleviate internal stress of the first inorganic encapsulation layer 410 and/or the second inorganic encapsulation layer 430. The organic encapsulation layer 420 may include a polymer-based material. The polymer-based material may include polyethylene terephthalate, polyethylene naphthalate, polycarbonate, polyimide, polyethylene sulfonate, polyoxymethylene, polyarylate, HMDSO, acrylic resin (e.g., polymethylmethacrylate, polyacrylic acid, etc.), or any combinations thereof.

The organic encapsulation layer 420 may be formed or provided by applying a flowable material including monomers and then reacting the monomers to form a polymer by bonding the monomers using heat or light such as ultraviolet light. Also, the organic encapsulation layer 420 may be formed or provided by applying a polymer material.

Even when cracks occur in the thin-film encapsulation layer 400 through the above-described multilayer structure, the thin-film encapsulation layer 400 may prevent the cracks from being connected between the first inorganic encapsulation layer 410 and the organic encapsulation layer 420 or between the organic encapsulation layer 420 and the second inorganic encapsulation layer 430. Therefore, it is possible to prevent or minimize the formation of a path through which external moisture or oxygen penetrates into the display area DA.

The anti-reflective layer 500 may be on the thin-film encapsulation layer 400. The anti-reflective layer 500 may include a light blocking layer 510 in which an opening 510_OP overlapping the emission area EA of the display element is defined, and a reflection adjustment layer 530 filling the opening 510_OP of the light blocking layer 510. The light blocking layer 510 may be on the thin-film encapsulation layer 400 and may include a body part 511 and a light absorbing agent 512 disposed inside the body part 511. Because the thin-film encapsulation layer 400 is on the low-reflection layer 300, the light blocking layer 510 may be on the low-reflection layer 300. In some embodiments, the opening 510_OP of the light blocking layer 510 may overlap the opening OP of the pixel defining layer 209, but a second width W2 of the opening 510_OP of the light blocking layer 510 may be greater than a first width W1 of the opening OP of the pixel defining layer 209.

The body part 511 is a portion that is distinct from the opening 510_OP of the light blocking layer 510 and may refer to a portion having a predetermined volume. The body part 511 may absorb visible light. In other words, the body part 511 may include a material that generally absorbs light in a wavelength band of about 380 nm to about 780 nm. Therefore, the body part 511 may have a gray color or a color close to black. The body part 511 may include carbon black, carbon nanotubes, a resin or paste including black dye, metal particles (e.g., nickel, aluminum, molybdenum, and alloys thereof), metal oxide particles (e.g., chromium oxide), or metal nitride particles (e.g., chromium nitride).

The light absorbing agent 512 is disposed in the body part 511 and may absorb light in a wavelength band of about 380 nm to about 500 nm. That is, the light absorbing agent 512 may absorb light in a blue light wavelength band. The light absorbing agent 512 may include a dye, a pigment, or a combination thereof. An absorption spectrum of the dye or the pigment included in the light absorbing agent 512 may have a peak in a wavelength band of about 500 nm or less. Therefore, the dye or the pigment may include yellowish materials. That is, the light absorbing agent 512 may include yellowish materials. In some embodiments, the light absorbing agent 512 may have a transmittance of about 0.5 percent (%) or less in a wavelength band of about 400 nm to about 490 nm. When the light absorbing agent 512 having the above transmittance is used, it may be easy to adjust the reflective color sense of the display apparatus.

External light incident on the display apparatus may be reflected from the display panel 10 to affect a color sense of an image provided by the display panel 10. In an embodiment, when the degree to which light of a predetermined wavelength is reflected is greater than the degree to which light of another wavelength is reflected, the reflected light may appear to have the color of the light of the predetermined wavelength as a whole, for example. Therefore, it may be necessary to adjust the reflective color sense in order to improve the display quality of the display apparatus. To this end, it is necessary to arrange the light absorbing agent 512 near the upper surface of the light blocking layer 510. The light blocking layer 510 may be formed or provided by applying a light blocking layer resin including the light absorbing agent 512 on the thin-film encapsulation layer 400 and then performing a light exposure process and a development process thereon. During the light exposure process, the light absorbing agent 512 may float in the vicinity of the upper surface of the light blocking layer resin within the light blocking layer resin. The light blocking layer resin cured during the light exposure process may form the body part 511. Through these processes, the light blocking layer 510 in the embodiment may be formed or provided. The amount of the light absorbing agent 512 per unit volume in a first portion of the light blocking layer 510 facing the substrate 100 (e.g., facing the bottom of the display apparatus in the −z-axis direction) may be less than the amount of the light absorbing agent 512 per unit volume in a second portion of the light blocking layer 510 facing opposite to the substrate 100 (e.g., facing the top of the display apparatus in the +z-axis direction). In other words, the concentration of the light absorbing agent 512 may increase toward the upper portion of the light blocking layer 510 (+z-axis direction).

Surface energy of the light absorbing agent 512 may be less than surface energy of the material included in the body part 511. In this case, during the light exposure process, the light absorbing agent 512 may float in the vicinity of the upper surface of the light blocking layer resin. The material included in the body part 511 may have a surface energy of about 40 dyne per centimeter (dyne/cm) to about 45 dyne/cm. Therefore, the light absorbing agent 512 may have a surface energy of less than 40 dyne/cm. In an embodiment, the light absorbing agent 512 may have a surface energy of about 15 dyne/cm to about 28 dyne/cm, for example. When a fluorine-based substituent is bonded to polymers constituting the light absorbing agent 512, the surface energy may be lowered. Therefore, in order for the light absorbing agent 512 to have low surface energy, the light absorbing agent 512 may include a material having the fluorine-based substituent.

By arranging the light blocking layer 510 including the light absorbing agent 512 on the thin-film encapsulation layer 400 as described above, the body part 511 may absorb visible light as a whole and the light absorbing agent 512 may additionally absorb light in a short wavelength band, that is, a blue light band. Therefore, the reflective color sense may be improved by reducing the reflectance of external light and preventing the reflected light from excessively including light in the blue light band.

In another embodiment, as illustrated in FIG. 4B, the light blocking layer 510 may further include a light absorbing agent 512 disposed inside a body part 511, and a protective agent 513 having a surface energy less than that of the light absorbing agent 512 and being capable of protecting the light absorbing agent 512. The protective agent 513 may have development resistance. That is, the protective agent 513 may not be dissolved in a developing solution. When a light blocking layer pattern is formed or provided, a light exposure process and a development process may be performed. In this case, when the light absorbing agent 512 has no development resistance, the light absorbing agent 512 may be removed by being dissolved in a developer such as tetra-methyl ammonium oxide (“TMAH”) or KOH in the developing process. Therefore, in order to prevent this problem, a portion having the highest concentration of the protective agent 513 may be disposed above a portion having the highest concentration of the light absorbing agent 512 during the light exposure process. To this end, the surface energy of the protective agent 513 may be less than the surface energy of the light absorbing agent 512. In an embodiment, the protective agent 513 may have a surface energy of about 12 dyne/cm to about 25 dyne/cm. In order to have such surface energy, the protective agent 513 may include a polymer material having a fluorine-based substituent, for example. In an embodiment, the protective agent 513 may include a polymer material, such as perfluoropolyether (“PFPE”), which does not hydrolyze, for example.

The light blocking layer 510 formed or provided as described above may include the light absorbing agent 512 and the protective agent 513 in the body part 511. The light blocking layer 510 may include a first portion facing the substrate 100 (e.g., facing the bottom of the display apparatus in the −z-axis direction), a second portion facing opposite to the substrate 100 (e.g., facing the top of the display apparatus in the +z-axis direction), and a third portion between the first portion and the second portion. In this case, the amount of the light absorbing agent 512 per unit volume in the third portion may be greater than the amount of the light absorbing agent 512 per unit volume in the first portion or the second portion. Also, the amount of the protective agent 513 per unit volume in the second portion may be greater than the amount of the protective agent 513 per unit volume in the first portion or the third portion. In other words, a portion having the highest concentration of the protective agent 513 may be disposed near the upper portion of the light blocking layer 510, and a portion having the highest concentration of the light absorbing agent 512 may be disposed relatively closer to the substrate 100 than the portion having the highest concentration of the protective agent 513 is to the substrate 100. Therefore, the protective agent 513 may prevent a large amount of the light absorbing agent 512 from being dissolved and removed in the developer during the development process.

In this manner, the protective agent 513 is desired in order to prevent the light absorbing agent 512 from being removed during the development process. However, when the light absorbing agent 512 has development resistance, the light blocking layer 510 may not include the protective agent 513.

The reflection adjustment layer 530 may fill the opening 510_OP of the light blocking layer 510. That is, the reflection adjustment layer 530 may be on the thin-film encapsulation layer 400 and the light blocking layer 510. The reflection adjustment layer 530 may absorb light having a wavelength of some bands among light reflected from the display apparatus or light incident from the outside of the display apparatus.

As illustrated in FIG. 5 showing an embodiment of the light transmittance of the reflection adjustment layer 530 provided in the display apparatus, the reflection adjustment layer 530 may absorb light in a first wavelength band of about 480 nm to about 505 nm and a second wavelength band of about 585 nm to about 605 nm. The light transmittance of the reflection adjustment layer 530 in the first wavelength band and the second wavelength band may be about 40% or less. That is, the reflection adjustment layer 530 may absorb light having a wavelength that does not belong to a wavelength band of red, green, or blue light of the organic light-emitting diode OLED. The reflectance measured on the surface of the reflection adjustment layer 530 in a specular component included (“SCI”) mode may be about 10% or less. Because the reflection adjustment layer 530 absorbs reflected external light, the visibility of an image provided by the display panel 10 may be improved.

The reflection adjustment layer 530 may be provided as an organic material layer including a dye, a pigment, or a combination thereof. The reflection adjustment layer 530 may include an oxazine-based compound, a cyanine-based compound, a tetraazaporphyrin-based compound, and a squarylium-based compound. In an embodiment, the reflection adjustment layer 530 may include a compound represented by one of Chemical Formulae 1 to 4 below, for example.

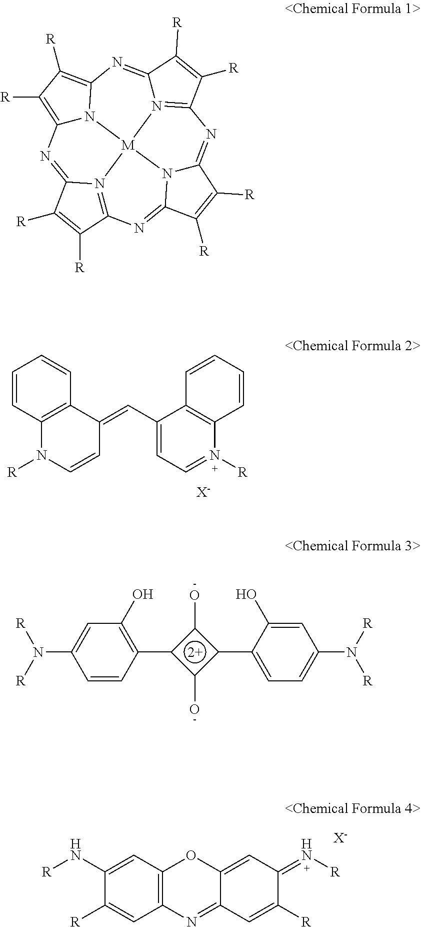

In Chemical Formulae 1 to 4, M is a metal, and X⁻ is a monovalent anion. Rs are identical to or different from each other, and may each include (i) hydrogen, deuterium (—D), —F, —Cl, —Br, —I, a hydroxyl group, a cyano group, or a nitro group, (ii) a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combinations thereof, (iii) a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combinations thereof, or (iv) —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Q₁ to Q₃, Q₁₁ to Q₁₃, Q₂₁ to Q₂₃, and Q₃₁ to Q₃₃ may each independently include hydrogen, heavy hydrogen, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combinations thereof.

In an embodiment, X⁻ may be a halide ion, a carboxylate ion, a nitrate ion, a sulfonate ion, or a bisulfate ion.

In an embodiment, X⁻ may be F⁻, Cl⁻, Br⁻, I⁻, CH₃COO⁻, NO₃⁻, HSO₄⁻, a propionate ion, a benzene sulfonate ion, or the like, for example.

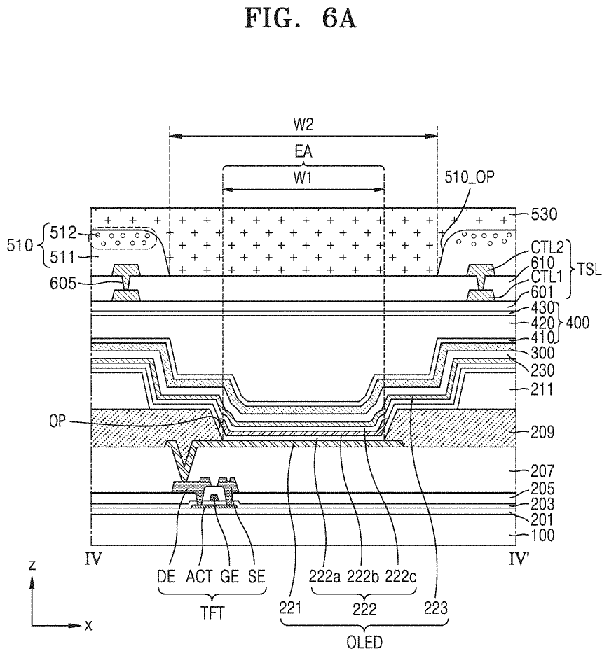

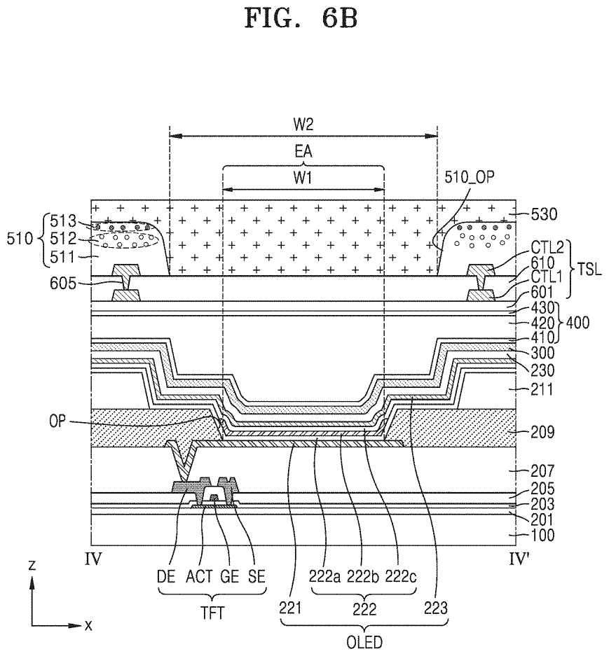

FIGS. 6A and 6B are cross-sectional views of an embodiment of a display apparatus. In FIGS. 6A and 6B, the same reference numerals as those in FIGS. 4A and 4B denote the same members, and redundant descriptions thereof will be omitted.

As illustrated in FIGS. 6A and 6B, a touch sensor layer TSL may be between a thin-film encapsulation layer 400 and a light blocking layer 510. The touch sensor layer TSL senses a user's touch input. The touch sensor layer TSL may sense a user's touch input by a method such as a resistive method or a capacitive method.

The touch sensor layer TSL may be on the thin-film encapsulation layer 400. The touch sensor layer TSL may include a first sub-conductive layer CTL1, a second sub-conductive layer CTL2, and a touch insulating layer 610. In an embodiment, the touch sensor layer TSL may further include a touch buffer layer 601 between the thin-film encapsulation layer 400 and the touch insulating layer 610.

The touch buffer layer 601 may be on the thin-film encapsulation layer 400. The touch buffer layer 601 may prevent damage to the thin-film encapsulation layer 400 and block an interference signal that may be generated when the touch sensor layer TSL is driven. The touch buffer layer 601 may include an inorganic insulating material or an organic material, such as silicon oxide (SiOₓ), silicon nitride (SiNₓ), or silicon oxynitride (SiOₓN_{y}). The touch buffer layer 601 may have a single layer or multilayer structure including the above-described inorganic insulating material or organic material.

The first sub-conductive layer CTL1, the touch insulating layer 610, and the second sub-conductive layer CTL2 may be sequentially stacked on the touch buffer layer 601. The first sub-conductive layer CTL1 and the second sub-conductive layer CTL2 may be below and above the touch insulating layer 610, respectively. The second sub-conductive layer CTL2 may act as a sensor which senses a user's touch input. The first sub-conductive layer CTL1 may act as a connecting part connecting the patterned second sub-conductive layer CTL2 in one direction. In some embodiments, both the first sub-conductive layer CTL1 and the second sub-conductive layer CTL2 may act as sensors. In this case, the first sub-conductive layer CTL1 and the second sub-conductive layer CTL2 may be electrically connected to each other through a contact hole 605. In this manner, as both the first sub-conductive layer CTL1 and the second sub-conductive layer CTL2 act as sensors, the resistance of the touch electrode decreases, so that a user's touch input is quickly sensed. In some embodiments, the first sub-conductive layer CTL1 and the second sub-conductive layer CTL2 may have a mesh structure so that light emitted from the organic light-emitting diode OLED may pass therethrough. In this case, the first sub-conductive layer CTL1 and the second sub-conductive layer CTL2 may be arranged not to overlap the emission area of the organic light-emitting diode OLED.

The first sub-conductive layer CTL1 and the second sub-conductive layer CTL2 may include a metal layer or a transparent conductive layer. The metal layer may include molybdenum (Mo), silver (Ag), titanium (Ti), copper (Cu), aluminum (Al), and any alloy thereof. The transparent conductive layer may include a transparent conductive oxide such as ITO, IZO, zinc oxide (ZnO), and indium tin zinc oxide (“ITZO”). In addition, the transparent conductive layer may include a conductive polymer such as poly(3,4-ethylenedioxythiophene) (“PEDOT”), metal nanowires, carbon nanotubes, or graphene.

The touch insulating layer 610 may include an inorganic material or an organic material. The inorganic material may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. The organic material may include at least one of an acrylic resin, a methacrylic resin, polyisoprene, a vinyl-based resin, an epoxy-based resin, a urethane-based resin, a cellulose-based resin, and a perylene-based resin.

As illustrated in FIG. 6A, the light blocking layer 510 including the light absorbing agent 512 and the reflection adjustment layer 530 may be on the touch sensor layer TSL. In an alternative embodiment, as illustrated in FIG. 6B, the light blocking layer 510 including the light absorbing agent 512 and the protective agent 513 and the reflection adjustment layer 530 may reduce external light reflected by the first sub-conductive layer CTL1 and the second sub-conductive layer CTL2 provided in the touch sensor layer TSL.

For reference, FIGS. 6A and 6B illustrate that the light blocking layer 510 including the light absorbing agent 512 is in contact with the touch sensor layer TSL, but the invention is not limited thereto. In an embodiment, an additional touch insulating layer (not illustrated) may cover the second sub-conductive layer CTL2 and the touch insulating layer 610, and the light blocking layer 510 including the light absorbing agent 512 and the reflection adjustment layer 530 may be disposed on the additional touch insulating layer, for example. The same may apply to the following embodiments and modifications thereof. The additional touch insulating layer may include an inorganic material or an organic material. The inorganic material may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. The organic material may include at least one of an acrylic resin, a methacrylic resin, polyisoprene, a vinyl-based resin, an epoxy-based resin, a urethane-based resin, a cellulose-based resin, and a perylene-based resin. Furthermore, the touch sensor layer TSL may be variously modified. In an embodiment, the touch sensor layer TSL may not include two conductive layers of the first sub-conductive layer CTL1 and the second sub-conductive layer CTL2, as illustrated in FIGS. 6A and 6B, and may include a single conductive layer, for example.

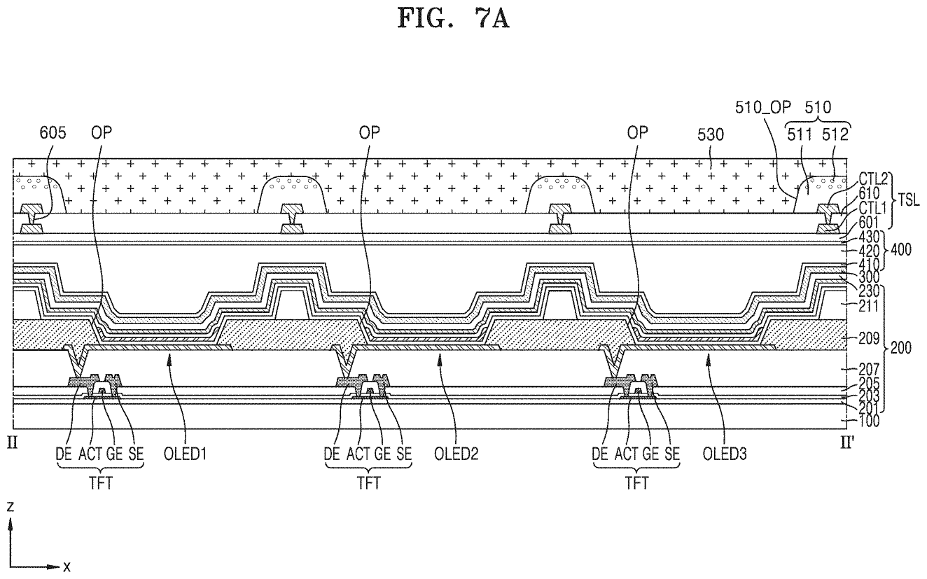

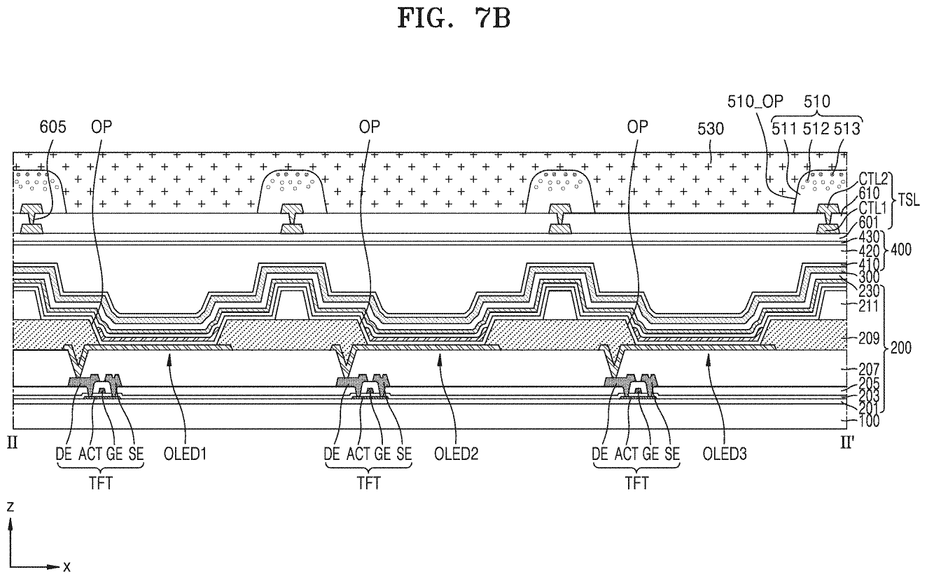

FIGS. 7A and 7B are cross-sectional views of an embodiment of a display apparatus. FIGS. 7A and 7B are cross-sectional views of the display apparatus taken along line II-II′ of FIG. 3A. In FIGS. 7A and 7B, the same reference numerals as those in FIGS. 6A and 6B denote the same members, and redundant descriptions thereof will be omitted.

As illustrated in FIG. 7A, in the display apparatus in the embodiment, a first organic light-emitting diode OLED1, a second organic light-emitting diode OLED2, and a third organic light-emitting diode OLED3, which emit light of different colors from each other, may be on a substrate 100. A low-reflection layer 300 may be unitary as a single body to correspond to, i.e., to be arranged on, the first organic light-emitting diode OLED1, the second organic light-emitting diode OLED2, and the third organic light-emitting diode OLED3. A thin-film encapsulation layer 400 may be on the low-reflection layer 300. Therefore, the thin-film encapsulation layer 400 may be unitary as a single body to correspond to, i.e., to be arranged on, the first organic light-emitting diode OLED1, the second organic light-emitting diode OLED2, and the third organic light-emitting diode OLED3. A touch sensor layer TSL may be on the thin-film encapsulation layer 400. Therefore, the touch sensor layer TSL may be unitary as a single body to correspond to, i.e., to be arranged on, the first organic light-emitting diode OLED1, the second organic light-emitting diode OLED2, and the third organic light-emitting diode OLED3.

A light blocking layer 510 may be on the touch sensor layer TSL. Also, openings 510_OP corresponding to emission areas of the first organic light-emitting diode OLED1, the second organic light-emitting diode OLED2, and the third organic light-emitting diode OLED3, respectively, may be defined in the light blocking layer 510. As described above, the light blocking layer 510 may include a body part 511 that absorbs visible light, and a light absorbing agent 512 that is disposed in the body part 511 and absorbs light in a wavelength band of about 380 nm to about 500 nm. A reflection adjustment layer 530 may fill the openings 510_OP of the light blocking layer 510 and may be unitary as a single body to correspond to, i.e., to be arranged on, the first organic light-emitting diode OLED1, the second organic light-emitting diode OLED2, and the third organic light-emitting diode OLED3. In an embodiment, the display apparatus may further include a capping layer 230 that is unitarily formed or provided as a single body between the first to third organic light-emitting diode OLED1 to OLED3 and the low-reflection layer 300.

The light absorbing agent 512 is disposed in the body part 511 and may absorb light having a wavelength band of about 380 nm to about 500 nm. That is, the light absorbing agent 512 may absorb light in a blue light wavelength band. The light absorbing agent 512 may include a dye, a pigment, or a combination thereof. An absorption spectrum of the dye or the pigment included in the light absorbing agent 512 may have an absorption peak in a wavelength band of about 500 nm or less. Therefore, the dye or the pigment may have a yellow color. That is, the light absorbing agent 512 may include yellowish materials. In some embodiments, the light absorbing agent 512 may have a transmittance of about 0.5% or less in a wavelength band of about 400 nm to about 490 nm.

The amount of the light absorbing agent 512 per unit volume in a first portion of the light blocking layer 510 facing the substrate 100 (e.g., facing the bottom of the display apparatus in the −z-axis direction) may be less than the amount of the light absorbing agent 512 per unit volume in a second portion of the light blocking layer 510 facing opposite to the substrate 100 (e.g., facing the top of the display apparatus in the +z-axis direction). In other words, the concentration of the light absorbing agent 512 may increase toward the upper portion of the light blocking layer 510 (+z-axis direction).

In order for the light absorbing agent 512 to have such a concentration distribution, surface energy of the light absorbing agent 512 may be less than surface energy of the material included in the body part 511. In an embodiment, the material included in the body part 511 may have a surface energy of about 40 dyne/cm to about 45 dyne/cm, and the light absorbing agent 512 may have a surface energy of about 15 dyne/cm to about 28 dyne/cm, for example. In order for the light absorbing agent 512 to have such surface energy, the light absorbing agent 512 may include a material having a fluorine-based substituent.

When the light absorbing agent 512 does not have development resistance, the light blocking layer 510 may further include a protective agent 513 having surface energy less than surface energy of the light absorbing agent 512, as illustrated in FIG. 7B. The light blocking layer 510 may include a first portion facing the substrate 100 (e.g., facing the bottom of the display apparatus in the −z-axis direction), a second portion of the light blocking layer 510 facing opposite to the substrate 100 (e.g., facing the top of the display apparatus in the +z-axis direction), and a third portion between the first portion and the second portion. In this case, the amount of the light absorbing agent 512 per unit volume in the third portion may be greater than the amount of the light absorbing agent 512 per unit volume in the first portion or the second portion. Also, the amount of the protective agent 513 per unit volume in the second portion may be greater than the amount of the protective agent 513 per unit volume in the first portion or the third portion. In other words, a portion having the highest concentration of the protective agent 513 may be disposed near the upper portion of the light blocking layer 510, and a portion having the highest concentration of the light absorbing agent 512 may be disposed relatively closer to the substrate 100 than the portion having the highest concentration of the protective agent 513 is to the substrate 100.

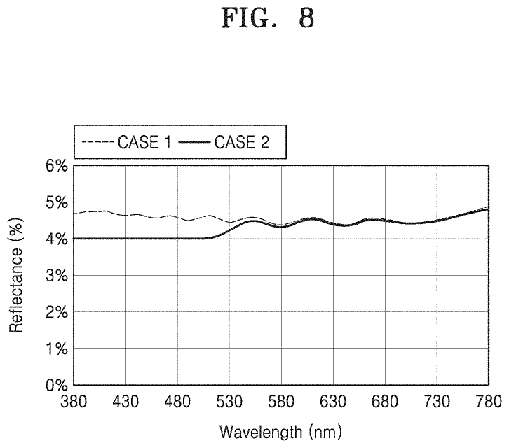

FIG. 8 is a graph showing reflectance of the light blocking layer 510 itself. In FIG. 8, case 1 shows the reflectance of the light blocking layer 510 itself when the light blocking layer 510 does not include the light absorbing agent 512, and case 2 shows the reflectance of the light blocking layer 510 itself when the light blocking layer 510 includes the light absorbing agent 512. As may be seen from FIG. 8, in case 1, the reflectance in the wavelength band of 380 nm to 530 nm is about 4.5% or more, and in case 2, the reflectance in the wavelength band of 380 nm to 530 nm is about 4%. As described above, it is confirmed that, when the light blocking layer 510 includes the light absorbing agent 512, the reflectance of external light in a short wavelength band is lowered. Therefore, when the light blocking layer 510 includes the light absorbing agent 512, visibility may be improved.

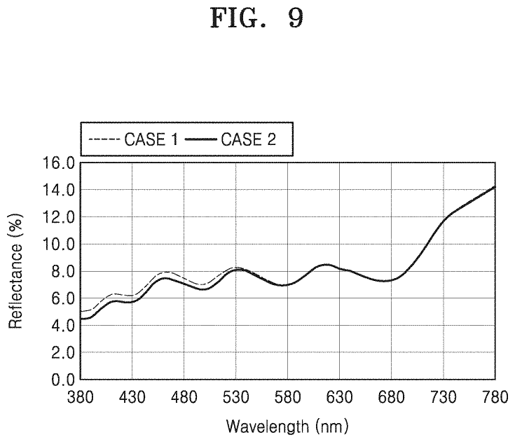

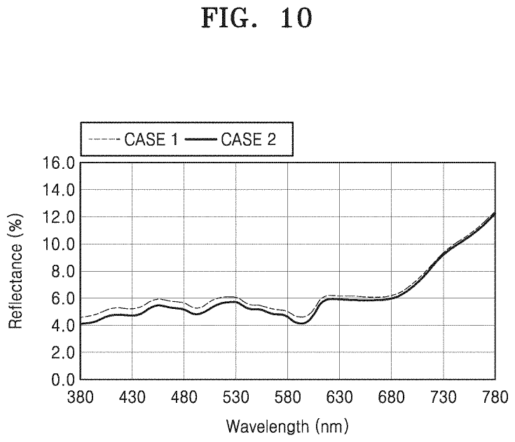

FIGS. 9 and 10 are graphs showing the reflectance of the display panel 10. Specifically, the graph of FIG. 9 shows the reflectance when the display panel 10 does not include the reflection adjustment layer 530. The graph of FIG. 10 shows the reflectance when the display panel 10 includes the reflection adjustment layer 530. In FIGS. 9 and 10, case 1 shows the reflectance of the display panel 10 when the light blocking layer 510 does not include the light absorbing agent 512, and case 2 shows the reflectance of the display panel 10 when the light blocking layer 510 includes the light absorbing agent 512. Referring to FIGS. 9 and 10, the reflectance in the wavelength band of 380 nm to 530 nm is lower in case 2 than in case 1. Also, it is confirmed that, when the display panel 10 includes the reflection adjustment layer 530, the reflectance in the visible light wavelength band is generally lowered.

As described above, according to embodiments, the display apparatus in which visibility is improved may be implemented. The scope of the invention is not limited by such an effect.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display apparatus comprising:
a display element on a substrate;
a low-reflection layer on the display element;
a light blocking layer on the low-reflection layer, the light blocking layer defining an opening corresponding to an emission area of the display element, and the light blocking layer comprising:
a body part which absorbs visible light; and
a light absorbing agent which is disposed in the body part and absorbs light in a wavelength band of about 380 nanometers to about 500 nanometers; and
a reflection adjustment layer filling the opening of the light blocking layer.

2. The display apparatus of claim 1, wherein an amount of the light absorbing agent per unit volume in a first portion of the light blocking layer facing the substrate is less than an amount of the light absorbing agent per unit volume in a second portion of the light blocking layer facing opposite to the substrate.

3. The display apparatus of claim 1, wherein surface energy of the light absorbing agent is less than surface energy of a material included in the body part.

4. The display apparatus of claim 1, wherein the light absorbing agent includes at least one of a dye and a pigment.

5. The display apparatus of claim 1, wherein the light absorbing agent includes a yellowish material.

6. The display apparatus of claim 1, wherein the light absorbing agent includes a material having a fluorine-based substituent.

7. The display apparatus of claim 1, wherein the light absorbing agent has a transmittance of about 0.5 percent or less in a wavelength band of about 400 nanometers to about 490 nanometers.

8. The display apparatus of claim 1, further comprising:
a thin-film encapsulation layer on the low-reflection layer; and
a touch sensor layer on the thin-film encapsulation layer,
wherein the light blocking layer is on the touch sensor layer.

9. The display apparatus of claim 1, wherein the light blocking layer further comprises a protective agent having a surface energy less than a surface energy of the light absorbing agent.

10. The display apparatus of claim 9, wherein the light blocking layer further comprises a first portion facing the substrate, a second portion facing opposite to the substrate, and a third portion between the first portion and the second portion,
an amount of the light absorbing agent per unit volume in the third portion is greater than an amount of the light absorbing agent per unit volume in the first portion or the second portion, and
an amount of the protective agent per unit volume in the second portion is greater than an amount of the protective agent per unit volume in the first portion or the third portion.

11. A display apparatus comprising:
a first display element, a second display element, and a third display element on a substrate and emitting light of different colors from each other;
a low-reflection layer disposed on the first to third display elements, the low-reflection layer being unitary as a single body;
a light blocking layer on the low-reflection layer, the light blocking layer defining openings corresponding to emission areas of the first to third display elements, and the light blocking layer comprising:
a body part which absorbs visible light; and
a light absorbing agent which is disposed in the body part and absorbs light in a wavelength band of about 380 nanometers to about 500 nanometers; and
a reflection adjustment layer filling the openings of the light blocking layer and unitary as a single body to correspond to the first to third display elements.

12. The display apparatus of claim 11, wherein an amount of the light absorbing agent per unit volume in a first portion of the light blocking layer facing the substrate is less than an amount of the light absorbing agent per unit volume in a second portion of the light blocking layer facing opposite to the substrate.

13. The display apparatus of claim 11, wherein surface energy of the light absorbing agent is less than surface energy of a material included in the body part.

14. The display apparatus of claim 11, wherein the light absorbing agent includes at least one of a dye and a pigment.

15. The display apparatus of claim 11, wherein the light absorbing agent includes a yellowish material.

16. The display apparatus of claim 11, wherein the light absorbing agent includes a material having a fluorine-based substituent.

17. The display apparatus of claim 11, wherein the light absorbing agent has a transmittance of about 0.5 percent or less in a wavelength band of about 400 nanometers to about 490 nanometers.

18. The display apparatus of claim 11, further comprising:
a thin-film encapsulation layer on the low-reflection layer; and
a touch sensor layer on the thin-film encapsulation layer,
wherein the light blocking layer is on the touch sensor layer.

19. The display apparatus of claim 11, wherein the light blocking layer further comprises a protective agent having a surface energy less than a surface energy of the light absorbing agent.

20. The display apparatus of claim 19, wherein the light blocking layer further comprises a first portion facing the substrate, a second portion facing opposite to the substrate, and a third portion between the first portion and the second portion,
an amount of the light absorbing agent per unit volume in the third portion is greater than an amount of the light absorbing agent per unit volume in the first portion or the second portion, and
an amount of the protective agent per unit volume in the second portion is greater than an amount of the protective agent per unit volume in the first portion or the third portion.
